(19) United States
(12) Patent Application Publication
(10) Pub. No.: US 2026/0122849 A1
(43) Pub. Date: Apr. 30, 2026

(54) ELECTRONIC DEVICE AND METHOD FOR ASSEMBLING ELECTRONIC DEVICE

(71) Applicant: DENSO CORPORATION, Kariya-city (JP)

(72) Inventor: Toshihiro MIYAKE, Kariya-city (JP)

(21) Appl. No.: 19/361,924

(22) Filed: Oct. 17, 2025

(30) Foreign Application Priority Data
Oct. 25, 2024 (JP) 2024-188247

(51) Int. Cl. H05K 7/20

(52) U.S. Cl. CPC H05K 7/20272

(57) ABSTRACT

An electronic device includes a housing, a substrate, a semiconductor, and a coolant flow-path structure. The housing has an opening. The substrate is arranged in the housing. The semiconductor is mounted on the substrate and arranged in the housing. The coolant flow-path structure is configured to allow a coolant to flow through the coolant flow-path structure, and positioned above the semiconductor. A protrusion is provided on either one of the coolant flow-path structure or the housing. A recess is provided on another of the coolant flow-path structure and the housing at a position corresponding to the protrusion. The protrusion is fitted to the recess such that a surface of the protrusion is spaced away from a surface of the recess.

### CROSS REFERENCE TO RELATED APPLICATION

The present application claims the benefit of priority from Japanese Patent Application No. 2024-188247 filed on October 25, 2024. The disclosures of all the above applications are incorporated herein.

### TECHNICAL FIELD

The present disclosure relates to an electronic device and a method for assembling an electronic device.

### BACKGROUND

Conventionally, an electronic component unit includes a substrate, a semiconductor package mounted on the substrate, a heat sink having a retainer plate mounted on the semiconductor package, and a reinforcing plate positioned behind the substrate.

### SUMMARY

According to at least one embodiment of the present disclosure, an electronic device includes a housing, a substrate, a semiconductor, and a coolant flow-path structure. The housing has an opening. The substrate is arranged in the housing. The semiconductor is mounted on the substrate and arranged in the housing. The coolant flow-path structure is configured to allow a coolant to flow through the coolant flow-path structure, and positioned above the semiconductor. A protrusion is provided on either one of the coolant flow-path structure or the housing. A recess is provided on another of the coolant flow-path structure and the housing at a position corresponding to the protrusion. The protrusion is fitted to the recess such that a surface of the protrusion is spaced away from a surface of the recess.

### BRIEF DESCRIPTION OF DRAWINGS

The details of one or more embodiments are set forth in the accompanying drawings and the description below. Other features and advantages will be apparent from the description and drawings, and from the claims.

FIG. 1 is a schematic cross-sectional view of an electronic device according to a first embodiment and a second embodiment.

FIG. 2A is a schematic view showing a second structure and connection members according to the first embodiment and the second embodiment.

FIG. 2B is a schematic view showing a housing according to the first embodiment and the second embodiment.

FIG. 3A is a schematic view showing a connecting pipe of the second structure.

FIG. 3B is a schematic view showing a connecting pipe of a first structure.

FIG. 4A is a schematic view illustrating a recess of the housing and a protrusion of the first structure.

FIG. 4B is a schematic view illustrating the recess of the housing and the protrusion of the first structure.

FIG. 4C is a schematic view illustrating the recess of the housing and the protrusion of the first structure.

FIG. 4D is a schematic view illustrating the recess of the housing and the protrusion of the first structure.

FIG. 5 is a schematic view illustrating a protrusion of the housing and a recess of the first structure according to another embodiment.

FIG. 6 is a schematic diagram illustrating an assembly method of the electronic device according to the first embodiment.

FIG. 7 is a schematic diagram illustrating an assembly method of the electronic device according to the second embodiment.

### DETAILED DESCRIPTIONS

According to a comparative example, an electronic component unit includes a substrate, a semiconductor package mounted on the substrate, a heat sink having a retainer plate mounted on the semiconductor package, and a reinforcing plate positioned behind the substrate. In the above-described electronic component unit, corners of the reinforcing plate and corners of the retainer plate are fastened together with fasteners, thereby pressing and securing the semiconductor package to the heat sink.

Since the above-described electronic component unit is partially fastened at the corners with the fasteners, which causes the semiconductor package and the heat sink to be bent, resulting in an uneven gap between the semiconductor package and the heat sink. Furthermore, since electronic components cannot be mounted on surfaces of the substrate in areas where the fasteners securing the semiconductor package and the heat sink together with the substrate are in contact with the substrate, the electronic component unit may become large.

According to one aspect of the present disclosure, an electronic device is capable of efficiently releasing a heat generated from a semiconductor, while being compact and lightweight.

An electronic device of one aspect of the present disclosure includes a housing, a substrate, a semiconductor, and a coolant flow-path structure. The housing has an opening. The substrate is arranged in the housing. The semiconductor is mounted on the substrate and arranged in the housing. The coolant flow-path structure is configured to allow a coolant to flow through the coolant flow-path structure, and positioned above the semiconductor. The coolant flow-path structure includes a first protrusion or a first recess. The housing includes a second recess or a second protrusion. The second recess is provided at a position corresponding to the first protrusion of the coolant flow-path structure and fitted to the first protrusion such that a surface of the second recess is spaced apart from a surface of the first protrusion. The second protrusion is provided at a position corresponding to the first recess of the coolant flow-path structure and fitted to the first recess such that a surface of the second protrusion is spaced apart from a surface of the first recess.

According to one aspect of the present disclosure, since the substrate including the semiconductor and the coolant flow-path structure are positioned in the housing without a retainer member that presses the semiconductor to the coolant flow-path structure, the substrate can be prevented from being bent and a gap between the semiconductor and the coolant flow-path structure can be made to be uniform. The electronic device can become compact and lightweight by having no retainer member. Furthermore, the gap between the protrusion and the recess absorbs assembly tolerances among the semiconductor, the substrate, and the housing, thereby maintaining a uniform distance between the semiconductor and the coolant flow-path structure. Therefore, heat generated from the semiconductor can be effectively dissipated, and the electronic device can become compact and lightweight.

In a method for assembling an electronic device, according to another aspect of the present disclosure, at least one structure of multiple structures is attached to a semiconductor. The multiple structures include a first structure and a second structure. The at least one structure includes the second structure. The semiconductor, to which at least the second structure is attached, is mounted on a substrate. The substrate, on which the semiconductor is mounted, is placed inside a housing by inserting the substrate through an opening of the housing. Coolant flow paths of the multiple structures are connected to each other. A protrusion of the first structure is fitted to a recess of the housing such that a surface of the protrusion of the first structure is spaced apart from a surface of the recess of the housing, or a recess of the first structure is fitted to a protrusion of the housing such that a surface of the recess of the first structure is spaced apart from a surface of the protrusion of the housing.

The electronic device can be assembled by attaching at least the second structure to the semiconductor, mounting the semiconductor on the substrate, inserting the substrate in a housing, connecting the coolant flow-paths of the multiple structures, and fitting the protrusion of the first structure in the recess of the housing or fitting the recess of the first structure in the protrusion of the housing.

In a method for assembling an electronic device, according to yet another aspect of the present disclosure, a semiconductor is mounted on a substrate. At least one structure of multiple structures is attached to the semiconductor mounted on the substrate. The multiple structures include a first structure and a second structure. The at least one structure includes the second structure. The substrate, on which the semiconductor is mounted, is placed inside a housing by inserting the substrate through an opening of the housing. Coolant flow paths of the multiple structures are connected to each other. A protrusion of the first structure is fitted to a recess of the housing such that a surface of the protrusion of the first structure is spaced apart from a surface of the recess of the housing, or a recess of the first structure is fitted to a protrusion of the housing such that a surface of the recess of the first structure is spaced apart from a surface of the protrusion of the housing.

The electronic device can be assembled by mounting the semiconductor on the substrate, attaching at least the second structure to the semiconductor which is mounted on the substrate, inserting the substrate in the housing, connecting the coolant flow-paths of the multiple structures, and fitting the protrusion of the first structure in the recess of the housing or fitting the recess of the first structure in the protrusion of the housing.

The embodiments of the present disclosure will be described below with reference to the drawings. In the following embodiments, portions that are the same as or equivalent to those described in a preceding embodiment are denoted by the same reference numerals, and a description of the same or equivalent portions may be omitted. When only some of the configuration elements are described in the embodiment, the remaining configuration elements can be referred from those described in the preceding embodiment. The following embodiments may be partially combined with each other even if such a combination is not explicitly described as long as there is no disadvantage with respect to such a combination.

### First Embodiment

### 1-1. Configuration of an Electronic Device

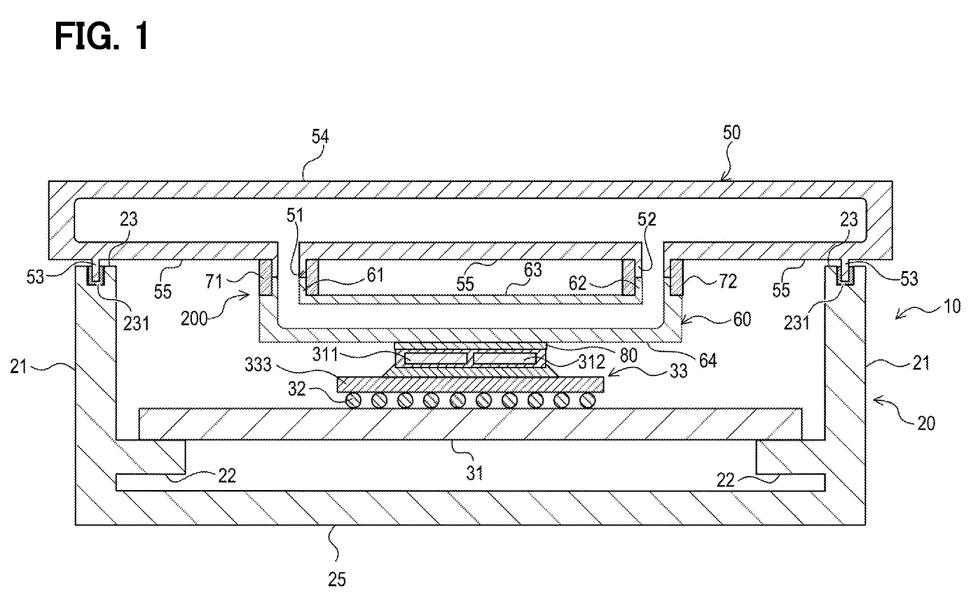

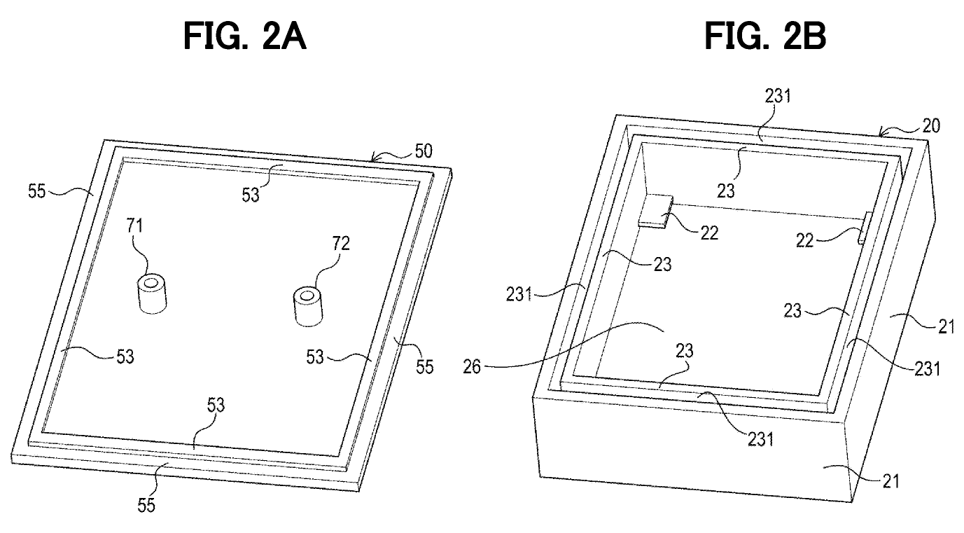

A configuration of an electronic device 10 according to the present embodiment will be described with reference to FIGS. 1, 2A, and 2B. The electronic device 10 includes a housing 20, a substrate 31, a semiconductor 33, a coolant flow-path structure 200, a first fitting portion 53, a second fitting portion 231, an adhesive layer 80, and a sealing member 90.

The housing 20 is made of a metal material such as aluminum, an aluminum alloy, copper, or a copper alloy. The housing 20 includes a rectangular parallelepiped shape with an opening at a top. The housing 20 includes four side faces 21, a bottom face 25, and four attachment portions 22, and forms an opening 26. The bottom face 25 faces the opening 26. The four attachment portions 22 are plate-shaped members and are positioned near the bottom face 25. As shown in FIG. 2B, the four attachment portions 22 are positioned at four corners inside the housing 20 and are connected perpendicularly to the four side faces 21, respectively. The four side faces 21 include four upper ends 23, respectively. An area surrounded by the four upper ends 23 corresponds to the opening 26.

The substrate 31 is smaller than the opening 26 of the housing 20, and is accommodated in the housing 20, and is attached to the attachment portions 22. In the present embodiment, the substrate 31 is secured to the attachment portions 22 with screws. The semiconductor 33 includes an interposer 333 and multiple chips 311 and 312. The multiple chips 311 and 312 are mounted on the interposer 333. The interposer 333 includes, for example, a wire electrically connecting the multiple chips 311 and 312, and a wire electrically connecting each of the multiple chips 311 and 312 and the substrate 31. Multiple solder balls 32 are provided between the interposer 333 and the substrate 31. The multiple solder balls 32 are arranged in a grid pattern. The interposer 333 is electrically connected to the substrate 31 via the multiple solder balls 32.

The adhesive layer 80 is thinly and evenly deposited on an upper surface of the semiconductor 33, i.e., an upper surface of the multiple chips 311 and 312. The adhesive layer 80 is made of, for example, a silicone resin or an epoxy resin. The coolant flow-path structure 200, described later, is adhered to the adhesive layer 80. The adhesive layer 80 has a thickness X1 and an elastic modulus Y1.

If the adhesive layer 80 is made of silicone resin, a heat resistance of a heat dissipation path from the semiconductor 33 to the coolant flow-path structure 200 can be improved. If the adhesive layer 80 is made of silicone resin or epoxy resin, which contains fillers having high thermal conductivity, the heat dissipation performance of the heat dissipation path can be improved.

The coolant flow-path structure 200 includes a flow path, a flow-path inlet, and a flow-path outlet. The flow path is provided inside the coolant flow-path structure 200, and a coolant flows in the flow path. The flow-path inlet is an opening through which the coolant flows from an outside of the coolant flow-path structure 200 to an inside of the coolant flow-path structure 200. The flow-path outlet is an opening through which the coolant flows from the inside of the coolant flow-path structure 200 to the outside of the coolant flow-path structure 200. The coolant flows from the outside of the coolant flow-path structure 200 to the flow-path via the flow-path inlet, flows through the flow-path, and then flows to the outside of the coolant flow-path structure 200 via the flow-path outlet. The coolant is a fluid that transfers heat from a higher temperature area to a lower temperature area. For example, the coolant is water.

The coolant flow-path structure 200 is made of a metal material such as aluminum, an aluminum alloy, cooper, or a copper alloy. In the present embodiment, the coolant flow-path structure 200 is made of the same metal material as the housing 20. Therefore, under a thermal cycling condition, a thermal stress caused by a difference in coefficients of thermal expansion between the housing 20 and the coolant flow-path structure 200 is reduced. The "thermal cycling" is a process in which the housing 20, the coolant flow-path structure 200, the semiconductor 33, and the substrate 31 are heated and expand due to a heat generated from the semiconductor 33 (described later), and then release the heat and return to their original states.

The coolant flow-path structure 200 is positioned upward of the semiconductor 33, i.e., the multiple chips 311 and 312. A portion of the coolant flow-path structure 200 is positioned inside the housing 20, and another portion of the coolant flow-path structure 200 is positioned outside of the housing 20 to cover the opening at a top of the housing 20. In other words, the coolant flow-path structure 200 serves as a lid for the housing 20.

Specifically, the coolant flow-path structure 200 includes multiple structures, and connection members 71 and 72. Each of the multiple structures includes a flow path in which the coolant flows. The connection members 71 and 72 connect flow paths of the multiple structures to each other so that the flow paths of the multiple structures communicate with the inlet and the outlet of the coolant flow-path structure 200. In the present embodiment, the multiple structures include a first structure 50 and a second structure 60. The first structure 50 is positioned outside the housing 20 and the second structure 60 is positioned inside the housing 20.

The first structure 50 is larger than the opening 26 of the housing 20 and covers the opening 26 to serve as the lid for the housing 20. The first structure 50 has a rectangular parallelepiped shape and forms the flow-path inlet, the flow-path outlet, and a flow path. The first structure 50 includes an inner surface 55, an outer surface 54, a first outlet 51, and a first inlet 52. In a case where the coolant flow-path structure 200 is attached to the housing 20, the inner surface 55 faces the inside of the housing 20 and the outer surface 54 faces away from the housing 20. The flow path of the first structure 50 is provided between the outer surface 54 and the inner surface 55.

The first outlet 51 has a cylindrical shape and is positioned on the inner surface 55. The first inlet 52 has a cylindrical shape and is positioned on the inner surface 55 at a location away from the first outlet 51. A length of the first inlet 52 is the same as a length of the first outlet 51. The first outlet 51 and the first inlet 52 are portions of the first structure 50 and pass through the inner surface 55 to communicate with the flow path inside the first structure 50.

The second structure 60 is smaller than the opening 26 of the housing 20 and smaller than the substrate 31. The second structure 60 has a rectangular parallelepiped shape. The second structure 60 includes a first face 63, a second face 64, a second inlet 61, and a second outlet 62. In a case where the coolant flow-path structure 200 is attached to the housing 20, the first face 63 faces the first structure 50 and the second face 64 faces the semiconductor 33. A flow path is provided between the first face 63 and the second face 64. The second structure 60 is arranged so that the second face 64 is in contact with the adhesive layer 80. As a result, the second face 64 is bonded to the upper surface of the semiconductor 33 via the adhesive layer 80.

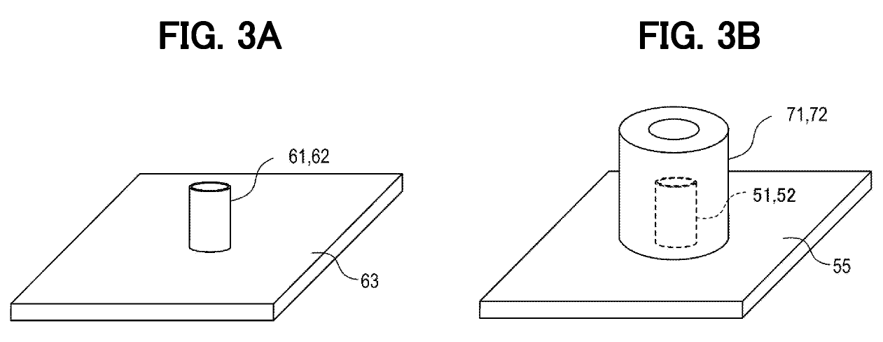

As shown in FIG. 3A, the second inlet 61 has a cylindrical shape and is positioned on the first face 63. A diameter of the second inlet 61 is the same as a diameter of the first outlet 51. The second outlet 62 has a cylindrical shape and is positioned on the first face 63 at a location away from the second inlet 61. The second inlet 61 and the second outlet 62 are portions of the flow path of the second structure 60 and pass through the first face 63 to communicate with the flow path inside the second structure 60. A length of the second outlet 62 is the same as a length of the second inlet 61. A diameter of the second outlet 62 is the same as a diameter of the first inlet 52. A distance between the second inlet 61 and the second outlet 62 is the same as a distance between the first outlet 51 and the first inlet 52. The first outlet 51 is connected to the second inlet 61 and the first inlet 52 is connected to the second outlet 62.

Specifically, the first outlet 51 is connected to the second inlet 61 by a connection member 71. On the other hand, a connection member 72 connects the first inlet 52 to the second outlet 62. The connection members 71 and 72 are rubber tubes or pipes. A length of the connection member 71 is approximately equal to a sum of the length of the first outlet 51 and the length of the second inlet 61. A length of the connection member 72 is approximately equal to a sum of the length of the first inlet 52 and the length of the second outlet 62.

As shown in FIG. 3B, an inner diameter of the connection member 71 is approximately the same as an outer diameter of the first outlet 51 and the second inlet 61. An inner diameter of the connection member 72 is approximately the same as an outer diameter of the first inlet 52 and the second outlet 62. The connection member 71 is connected to the first outlet 51 so that an outer surface of the first outlet 51 is in contact with an inner surface of the connection member 71. The connection member 72 is connected to the first inlet 52 so that an outer surface of the first inlet 52 is in contact with an inner surface of the connection member 72. The connection members 71 and 72 may be connected to the first outlet 51 and the first inlet 52 using a device that enables connection with a single push. The second inlet 61 is inserted into the connection member 71, and the second outlet 62 is inserted into the connection member 72. As a result, the flow path of the first structure 50 is connected to the flow path of the second structure 60.

Therefore, the coolant flows in the flow path of the first structure 50 via the flow-path inlet, and flows through the flow path of the first structure 50. Additionally, the coolant flows out from the first outlet 51, flows into the flow path of the second structure 60 via the second inlet 61, and then flows through the flow path of the second structure 60. Furthermore, the coolant flows out from the second outlet 62, returns to the flow path of the first structure 50 via the first inlet 52, flows through the flow path of the first structure 50, and then flows out from the flow-path outlet.

In another embodiment, the coolant flow-path structure 200 may be made of a metal material different from that of the housing 20. In another embodiment, the electronic device 10 may not include the adhesive layer 80 positioned between the semiconductor 33 and the coolant flow-path structure 200. In this case, the second structure 60 may be positioned on the semiconductor 33 so that the second face 64 is in contact with the upper surface of the semiconductor 33.

In another embodiment, the first structure 50 and the second structure 60 may be integrated. In other words, the coolant flow-path structure 200 may be a single structure. Alternatively, the coolant flow-path structure 200 may include three or more structures, with one or more structures connected between the first structure 50 and the second structure 60 and/or on the upper side of the second structure 60.

The first fitting portion 53 is provided on the first structure 50. As shown in FIG. 2A, the first fitting portion 53 is provided on the inner surface 55 of the first structure 50. Specifically, the first fitting portion 53 is provided inward of an outer edge of the inner surface 55 and extends along the outer edge of the inner surface 55. In the present embodiment, the first fitting portion 53 is formed as a protrusion protruding from the inner surface 55. In the present embodiment, the first fitting portion 53 corresponds to a first protrusion of the present disclosure.

In the present embodiment, the first fitting portion 53 is integrated with the coolant flow-path structure 200, specifically, the first structure 50. For example, the first structure 50 and the first fitting portion 53 are integrally formed using a single mold. This structure reduces the number of components of the electronic device 10.

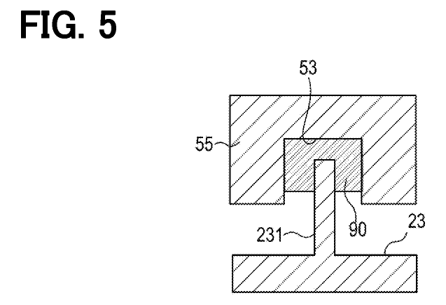

In another embodiment, as shown in FIG. 5, the first fitting portion 53 may be formed as a recess on the inner surface 55. In this case, the first fitting portion 53 corresponds to a first recess of the present disclosure. Furthermore, in another embodiment, the first fitting portion 53 may be formed separately from the first structure 50 and attached to the inner surface 55 by, for example, adhesive, brazing, or welding.

The second fitting portion 231 is provided at a position of the housing 20 corresponding to the first fitting portion 53 in a state where the coolant flow-path structure 200 is bonded to or placed on the semiconductor 33. Specifically, as shown in FIG. 2B, the second fitting portion 231 is provided inward of outer edges of the upper ends 23 and extends along the outer edges of the upper ends 23.

In the present embodiment, the second fitting portion 231 is formed as a recess corresponding to the first fitting portion 53. In the present embodiment, the second fitting portion 231 corresponds to a second recess of the present disclosure. In the present embodiment, the second fitting portion 231 is formed integrally with the housing 20. For example, the housing 20 and the second fitting portion 231 are integrally formed using a single mold. This structure reduces the number of components of the electronic device 10.

In another embodiment, as shown in FIG. 5, when the first fitting portion 53 is formed as a recess, the second fitting portion 231 may be formed as a protrusion protruding from the upper ends 23. In this case, the second fitting portion 231 corresponds to a second protrusion of the present disclosure. Furthermore, in another embodiment, the second fitting portion 231 may be formed separately from the housing 20 and attached to the upper ends 23 of the housing 20 by, for example, adhesive, brazing, or welding.

In a state where the coolant flow-path structure 200 is bonded to or placed on the semiconductor 33, the first fitting portion 53 is fitted into the second fitting portion 231. In other words, the protrusion of the first fitting portion 53 is fitted into the recess of the second fitting portion 231. The first fitting portion 53 fits into the second fitting portion 231 in a state where a surface of the first fitting portion 53 is spaced apart from a surface of the second fitting portion 231. In other words, the first fitting portion 53 is fitted into the second fitting portion 231 in a state where a surface of the protrusion is away from a surface of the recess and a gap is created between the surface of the protrusion and the surface of the recess. Additionally, in a state where the inner surface 55 is spaced apart from the upper ends 23, the first fitting portion 53 is fitted into the second fitting portion 231. In other words, the coolant flow-path structure 200 is assembled to the housing 20 in a state where the coolant flow-path structure 200 is not in contact with the housing 20.

Additionally, in another embodiment, even if the first fitting portion 53 is formed as the recess and the second fitting portion 231 is formed as the protrusion, the first fitting portion 53 is fitted to the second fitting portion 231 in a state where the surface of the recess spaced apart from the surface of the protrusion.

When the coolant flow-path structure 200 is assembled to the housing 20, the second structure 60 is positioned inside the housing 20, and the first structure 50 is positioned above the housing 20 and covers the opening 26 of the housing 20. Heat generated from the semiconductor 33 is transferred to the coolant in the coolant flow-path structure 200 via the adhesive layer 80, flows through the coolant flow-path structure 200 together with the coolant, and is dissipated to an outside of the coolant flow-path structure 200. Furthermore, the heat generated from the semiconductor 33 is transferred through the surfaces of the coolant flow-path structure 200 and the housing 20 and is dissipated to the outside.

The sealing member 90 is provided between the first fitting portion 53 and the second fitting portion 231. In other words, the sealing member 90 is provided between the protrusion and the recess. The sealing member 90 fills the gap between the housing 20 and the coolant flow-path structure 200, specifically, the gap between the housing 20 and the first structure 50, thereby sealing the housing 20. The sealing member 90 is, for example, a silicone resin, an epoxy resin, or a metal. When the sealing member 90 is a silicone resin or an epoxy resin, an airtightness of the housing 20 is improved, and a heat resistance of a heat dissipation path from the coolant flow-path structure 200 to the housing 20 is improved. Alternatively, when the sealing member 90 is a metal such as solder or brazing material, the thermal resistance of the heat dissipation path from the coolant flow-path structure 200 to the housing 20 is reduced. In other words, the heat dissipation performance of the heat dissipation path from the coolant flow-path structure 200 to the housing 20 is improved.

The sealing member 90 has a thickness X2 and an elastic modulus Y2. The thickness X1 is smaller than the thickness X2, and the elastic modulus Y1 is larger than the elastic modulus Y2. As a result, the sealing member 90 is more likely to be deformed than the adhesive layer 80. When a stress occurs under a thermal cycling condition due to a difference between a thermal expansion coefficient of the coolant flow-path structure 200, the semiconductor 33, and the substrate 31 and a thermal expansion coefficient of the housing 20, the sealing member 90 is deformed more than the adhesive layer 80 and absorbs the thermal stress. Therefore, the thermal stress applied to the adhesive layer 80 is reduced.

1-2. Functions of the First Fitting Portion and the Second Fitting Portion

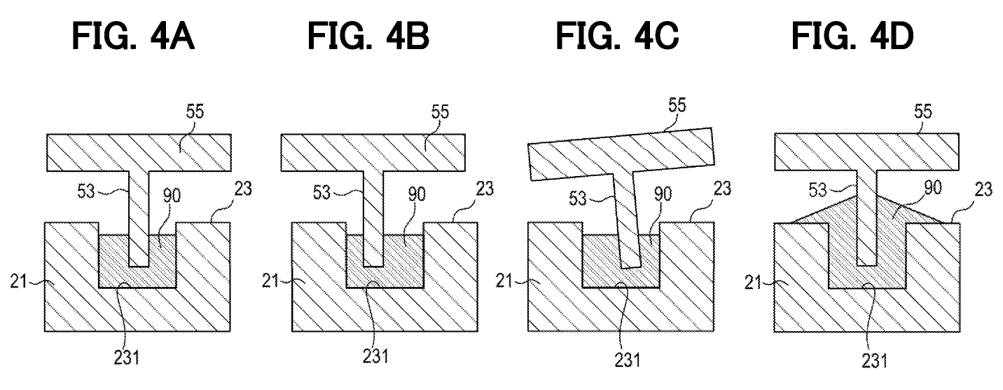

Since the gap (hereinafter referred to as a first gap) is created between the surface of the first fitting portion 53 and the surface of the second fitting portion 231, assembly tolerances of the coolant flow-path structure 200, the semiconductor 33, and the substrate 31 to the housing 20 are absorbed by the gap, thereby maintaining the coolant flow-path structure 200 and the housing 20 to be fitted to each other. Furthermore, a space between the semiconductor 33 and the coolant flow-path structure 200, specifically, a space between the semiconductor 33 and the second structure 60, is maintained uniform, and the coolant flow-path structure 200 and the housing 20, specifically, the first structure 50 and the housing 20 are maintained to be fitted to each other. FIG. 4A illustrates a state where the coolant flow-path structure 200, the semiconductor 33, and the substrate 31 are assembled to the housing 20 at the reference position with almost no assembly tolerance. FIG. 4B illustrates a state where at least one of the coolant flow-path structure 200, the semiconductor 33, and the substrate 31 is assembled to the housing 20 at a position deviated in the horizontal direction from the reference position. Even in this case, the first gap absorbs the deviation in the horizontal direction.

In addition to the first gap, the gap (hereinafter, referred to as a second gap) between the inner surface 55 and the upper ends 23 can absorb different assembly tolerances. FIG. 4C illustrates a state where at least one of the coolant flow-path structure 200, the semiconductor 33, and the substrate 31 is assembled to the housing 20 at a position that is inclined from the reference position and deviated in the vertical direction. Even in this case, the first gap and the second gap absorb the deviation in the vertical direction and the horizontal direction. As illustrated in FIG.4D, even if the sealing member 90 is overflowed from the first gap, the excess sealing member 90 is absorbed by the second gap, thereby maintaining a distance between the semiconductor 33 and the coolant flow-path structure 200 uniform.

1-3. Assembly Method

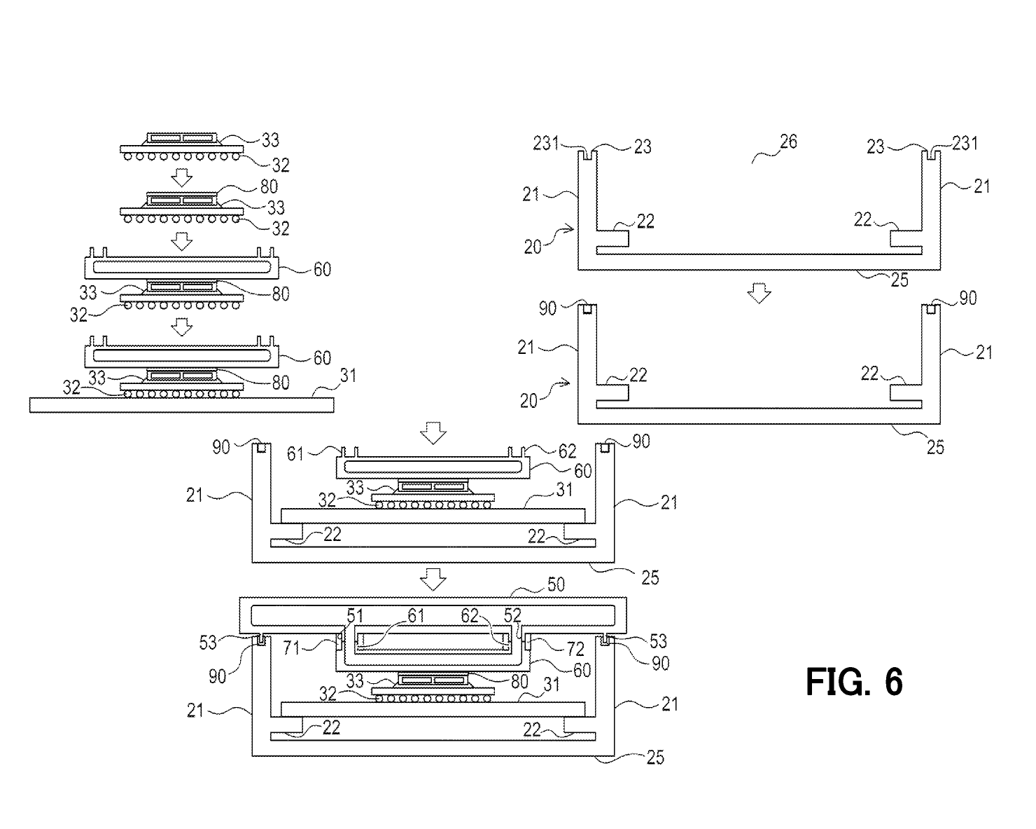

A method for assembling the electronic device 10 will be described with reference to FIG. 6. First, the adhesive layer 80 is deposited thinly and evenly on the upper surface of the semiconductor 33. Next, the second structure 60 is placed on the adhesive layer 80, and the upper surface of the semiconductor 33 and the second structure 60 are pressurized and heated to harden the adhesive layer 80, thereby integrating the semiconductor 33, the adhesive layer 80, and the second structure 60. Next, the semiconductor 33 to which the second structure 60 is bonded is mounted on the substrate 31. On the other hand, the sealing member 90 is injected into the second fitting portion 231 of the housing 20.

Additionally, the substrate 31 on which the semiconductor 33 is mounted is inserted into the housing 20 through the opening 26 at the top of the housing 20, and the substrate 31 is secured to the attachment portions 22 with screws. Next, the flow path of the second structure 60 and the flow path of the first structure 50 are connected to each other, and the first fitting portion 53 of the first structure 50 is fitted to the second fitting portion 231 of the housing 20.

Specifically, the second inlet 61 and the second outlet 62 of the second structure 60 are connected to the connection members 71 and 72 which are connected to the first outlet 51 and the first inlet 52 of the first structure 50. As a result, the flow path of the first structure 50 is connected to the flow path of the second structure 60. Additionally, the protrusion of the first fitting portion 53 is fitted into the recess of the second fitting portion 231 so that the surface of the protrusion is spaced apart from the surface of the recess. In another embodiment, if the coolant flow-path structure 200 includes three or more structures, respective flow paths of the three or more structures are connected by connection members.

### 1-4. Effects

According to the first embodiment described in detail above, the following effects can be obtained.

(1) The substrate 31 on which the semiconductor 33 is mounted and the coolant flow-path structure 200 can be assembled to the housing 20 without a retainer member pressing the semiconductor 33 to the coolant flow-path structure 200. Therefore, the semiconductor 33, the coolant flow-path structure 200, and the substrate 31 can be prevented from being bent, and a space between the semiconductor 33 and the coolant flow-path structure 200 can be thin and uniform. Additionally, the electronic device 10 can become compact and lightweight by having no retainer member. Furthermore, the first gap can absorb assembly tolerances among the coolant flow-path structure 200, the semiconductor 33, the substrate 31, and the housing 20, thereby maintaining a distance between the semiconductor 33 and the coolant flow-path structure 200 thin and uniform. Therefore, the heat generated from the semiconductor 33 can be effectively dissipated and the electronic device 10 can become compact and lightweight.

(2) The first outlet 51 of the first structure 50 is connected to the second inlet 61 of the second structure 60, and the first inlet 52 of the first structure 50 is connected to the second outlet 62 of the second structure 60, thereby forming a flow path. Furthermore, since the second structure 60 is made to be in contact with or bonded to the semiconductor 33, the heat generated from the semiconductor 33 is transferred to the coolant within the second structure 60, and then is released by propagating through the formed flow path. Therefore, a minimum portion of the coolant flow-path structure 200 can be brought into contact with or bonded to the semiconductor 33 to ensure a heat dissipation path with high heat dissipation performance.

(3) Since the first structure 50 is larger than the opening 26, the first fitting portion 53 on the inner surface 55 of the first structure 50 can be fitted into the second fitting portion 231 on the upper ends 23 of the housing 20. As a result, the first structure 50 can be supported by the housing 20 via the sealing member 90. Furthermore, since the vibration of the coolant flow-path structure 200 caused by the flow of the coolant can be prevented from propagating to the semiconductor 33, a fatigue strength of the semiconductor 33 can be improved.

(4) Since the housing 20 and the coolant flow-path structure 200 are made of the same metal material, a thermal stress generated under the thermal cycling condition due to the difference in thermal expansion coefficients between the housing 20 and the coolant flow-path structure 200 can be reduced. As a result, thermal fatigue life of the housing 20 and the coolant flow-path structure 200 can be extended under the thermal cycling condition.

(5) Since the first fitting portion 53 is formed integrally with the coolant flow-path structure 200, the number of components can be reduced, thereby reducing costs. (6) Since the second fitting portion 231 is formed integrally with the housing 20, the number of components can be reduced, thereby reducing costs.

(7) Since the semiconductor 33 is bonded to the coolant flow-path structure 200 via the adhesive layer 80, the distance between the semiconductor 33 and the coolant flow-path structure 200 can be stably and uniformly narrowed.

(8) When the adhesive layer 80 is made of a silicone resin, a heat dissipation path with high heat resistance can be realized. When the adhesive layer 80 is made of a silicone resin or an epoxy resin containing fillers having high thermal conductivity, the heat dissipation performance of the heat dissipation path can be further improved.

(9) Since the sealing member 90 are positioned between the first fitting portion 53 and the second fitting portion 231, the first gap can absorb assembly tolerances between the coolant flow-path structure 200 and the housing 20, between the semiconductor 33 and the housing 20, and between the substrate 31 and the housing 20, while the airtightness of the housing 20 is secured.

(10) When the sealing member 90 is a silicone resin or an epoxy resin, the airtightness of the housing 20 can be improved, and the heat resistance of the heat dissipation path from the coolant flow-path structure 200 to the housing 20 can be improved.

(11) When the sealing member 90 is made of metal, the thermal resistance of the heat dissipation path from the semiconductor 33 through the coolant flow-path structure 200 to the housing 20 is reduced, so that the heat generated from the semiconductor 33 can be dissipated more efficiently.

(12) The thickness X1 of the adhesive layer 80 is smaller than the thickness X2 of the sealing member 90, and the elastic modulus Y1 of the adhesive layer 80 is greater than the elastic modulus Y2 of the sealing member 90. As a result, when a stress occurs due to a difference in the thermal expansion coefficients among the coolant flow-path structure 200, the semiconductor 33, the substrate 31 and the housing 20 under the thermal cycling condition, the sealing member 90 undergoes greater deformation and absorbs more of the thermal stress than the adhesive layer 80, thereby reducing the thermal stress acting on the adhesive layer 80. Consequently, the thermal cycle fatigue life of the adhesive layer 80 can be secured, and a heat dissipation path with an excellent heat dissipation performance from the semiconductor 33 to the coolant flow-path structure 200 can be maintained.

(13) The first fitting portion 53 is provided on the inner surface 55 of the first structure 50, and the second fitting portion 231 is provided on the upper ends 23 of the housing 20. This allows the first fitting portion 53 to be fitted into the second fitting portion 231, and the first structure 50 can be supported by the housing 20 via the sealing member 90. Furthermore, the vibration of the coolant flow-path structure 200 caused by the flow of the refrigerant is prevented from propagating to the semiconductor 33, and the fatigue strength of the semiconductor 33 can be increased.

(14) The second structure 60 is attached to the semiconductor 33, and then the semiconductor 33 with the second structure 60 is mounted on the substrate 31. The substrate 31 is inserted into the housing 20, the flow path of the first structure 50 is connected to the flow path of the second structure 60, and then the first fitting portion 53 is fitted to the second fitting portion 231. According to this process, the electronic device 10 can be assembled.

### Second Embodiment

### 2-1. Differences from First Embodiment

Since a basic configuration of a second embodiment is similar to the first embodiment, differences will be described below. The same reference numerals as those in the first embodiment indicate the same configuration, and refer to the preceding descriptions.

A configuration of an electronic device 10 according to the second embodiment is similar to the configuration of the electronic device 10 according to the first embodiment, but an assembly method is different. The assembly method of the electronic device 10 according to the second embodiment will be described below.

### 2-2. Assembly Method

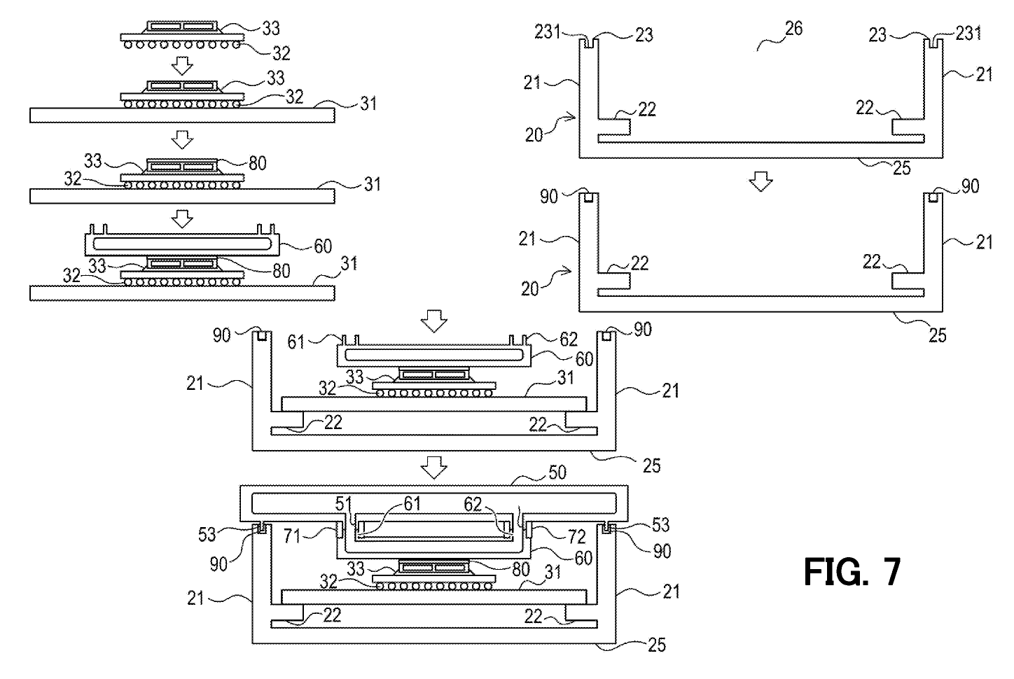

With reference to FIG. 7, a method of assembling the electronic device 10 will be described. First, the semiconductor 33 is mounted on the substrate 31. Next, an adhesive layer 80 is formed thinly and uniformly on the upper surface of the semiconductor 33 mounted on the substrate 31. Next, the second structure 60 is placed on the adhesive layer 80, and the upper surface of the semiconductor 33 and the second structure 60 are pressurized and heated to harden the adhesive layer 80, thereby integrating the semiconductor 33, the adhesive layer 80, and the second structure 60. Meanwhile, the sealing member 90 is injected into the second fitting portion 231 of the housing 20.

Then, the substrate 31 on which the semiconductor 33 is mounted is inserted into the housing 20 through the opening 26 at the top of the housing 20, and the substrate 31 is fixed to the attachment portions 22 with screws. Next, the flow path of the second structure 60 and the flow path of the first structure 50 are connected to each other, and the first fitting portion 53 of the first structure 50 is fitted into the second fitting portion 231 of the housing 20.

### 2-3. Effects

According to the second embodiment described in detail above, the effects (1) to (13) of the above-described first embodiment can be obtained, and further, the following effects can be obtained.

(15) The semiconductor 33 is mounted on the substrate 31, and then the second structure 60 is attached to the semiconductor 33 mounted on the substrate 31. The substrate 31 is inserted into the housing 20, the flow path of the first structure 50 is connected to the flow path of the second structure 60, and then the first fitting portion 53 is fitted to the second fitting portion 231. According to this process, the electronic device 10 can be assembled.

### 3. Other Embodiments

Although the embodiments of the present disclosure have been described above, the present disclosure is not limited to the embodiments described above, and various modifications can be made to implement the present disclosure.

Multiple functions of one element in the above embodiments may be implemented by multiple elements, or one function of one element may be implemented by multiple elements. Further, multiple functions of multiple elements may be implemented by one element, or one function implemented by multiple elements may be implemented by one element. A part of the configuration of the above-described embodiments may be omitted. Further, at least part of the configuration of the above-described embodiments may be added to or replaced with a configuration of another embodiment described above.

While the present disclosure has been described with reference to embodiments thereof, it is to be understood that the disclosure is not limited to the embodiments and constructions. To the contrary, the present disclosure is intended to cover various modification and equivalent arrangements. In addition, while the various elements are shown in various combinations and configurations, which are exemplary, other combinations and configurations, including more, less or only a single element, are also within the spirit and scope of the present disclosure.

What is claimed is:

1. An electronic device, comprising:
a housing having an opening;
a substrate arranged in the housing;
a semiconductor mounted on the substrate and arranged in the housing;
a coolant flow-path structure configured to allow a coolant to flow through the coolant flow-path structure, and positioned above the semiconductor;
a protrusion provided on either one of the coolant flow-path structure or the housing; and
a recess provided on another of the coolant flow-path structure and the housing at a position corresponding to the protrusion, wherein
the protrusion is fitted to the recess such that a surface of the protrusion is spaced away from a surface of the recess.

2. The electronic device according to claim 1, wherein
the coolant flow-path structure includes multiple structures having flow paths for the coolant, and connection members that connect the flow paths of the multiple structures, and
the multiple structures include a first structure positioned outside the housing and a second structure positioned inside the housing.

3. The electronic device according to claim 2, wherein
the first structure is larger than the opening and covers the opening.

4. The electronic device according to claim 1, wherein
the housing and the coolant flow-path structure are made of a same metal material.

5. The electronic device according to claim 1, wherein
the protrusion is integrally formed with the one of the coolant flow-path structure and the housing.

6. The electronic device according to claim 1, wherein
the recess is integrally formed with the other of the coolant flow-path structure and the housing.

7. The electronic device according to claim 1, further comprising
an adhesive layer between the semiconductor and the coolant flow-path structure.

8. The electronic device according to claim 1, further comprising
a sealing member between the protrusion and the recess.

9. The electronic device according to claim 7, wherein
the adhesive layer is made of a silicone resin or an epoxy resin.

10. The electronic device according to claim 8, wherein
the sealing member is made of a silicone resin or an epoxy resin.

11. The electronic device according to claim 8, wherein
the sealing member is made of a metal.

12. The electronic device according to claim 7, further comprising
a sealing member between the protrusion and the recess, wherein
a thickness of the adhesive layer is smaller than a thickness of the sealing member, and
an elastic modulus of the adhesive layer is larger than an elastic modulus of the sealing member.

13. The electronic device according to claim 3, wherein
the opening is enclosed by an upper end of the housing,
the first structure includes an inner surface facing an inside of the housing and an outer surface opposite the inner surface,
either one of the protrusion or the recess is positioned on the inner surface, and
another of the recess and the protrusion is positioned on the upper end.

14. A method for assembling an electronic device, the method comprising:
attaching at least one structure of multiple structures to a semiconductor, the multiple structures including a first structure and a second structure, the at least one structure including the second structure;
mounting the semiconductor, to which at least the second structure is attached, on a substrate;
placing the substrate, on which the semiconductor is mounted, inside a housing by inserting the substrate through an opening of the housing;
connecting coolant flow paths of the multiple structures to each other; and
(i) fitting a protrusion of the first structure to a recess of the housing such that a surface of the protrusion of the first structure is spaced apart from a surface of the recess of the housing, or
(ii) fitting a recess of the first structure to a protrusion of the housing such that a surface of the recess of the first structure is spaced apart from a surface of the protrusion of the housing.

15. A method for assembling an electronic device, the method comprising:
mounting a semiconductor on a substrate;
attaching at least one structure of multiple structures to the semiconductor mounted on the substrate, the multiple structures including a first structure and a second structure, the at least one structure including the second structure;
placing the substrate, on which the semiconductor is mounted, inside a housing by inserting the substrate through an opening of the housing;
connecting coolant flow paths of the multiple structures to each other; and
(i) fitting a protrusion of the first structure to a recess of the housing such that a surface of the protrusion of the first structure is spaced apart from a surface of the recess of the housing, or
(ii) fitting a recess of the first structure to a protrusion of the housing such that a surface of the recess of the first structure is spaced apart from a surface of the protrusion of the housing.
